(19) United States
(12) Patent Application Publication
(10) Pub. No.: US 2026/0123206 A1
(43) Pub. Date: Apr. 30, 2026

(54) DISPLAY PANEL

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/369,370

(22) Filed: Oct. 27, 2025

(30) Foreign Application Priority Data
Oct. 31, 2024 (CN) 202411552726.6

(51) Int. Cl. H10K 59/127; H10K 59/122; H10K 59/131; H10K 102/00

(52) U.S. Cl. CPC H10K 59/1275; H10K 59/122; H10K 59/131; H10K 2102/351

(57) ABSTRACT

The present disclosure provides a display panel, the display panel includes a glass substrate, a plurality of light-emitting units, a plurality of first bonding portions, and a silicon-based driving substrate. The glass substrate includes a first surface and a second surface, the glass substrate defines a plurality of conductive vias. The silicon-based driving substrate includes a buffer layer and a plurality of first bonding electrodes. The glass substrate and the buffer layer cooperate to form an accommodating groove, a reaction layer is arranged in the accommodating groove to absorb gas. The display panel can avoid the problem that directly fabricating the light-emitting units on the silicon-based driving substrate damages the pixel driving circuit and causes a reduction in product yield, reduce the damage of the gas to each film layer of the display panel, improve the reliability and durability of the display panel, and effectively increase the service life.

### CROSS REFERENCE TO RELATED APPLICATIONS

The present disclosure claims priority to Chinese Patent Application No. 202411552726.6, files on October 31, 2024, the contents of which are herein incorporated by reference in their entirety.

### TECHNICAL FIELD

The present disclosure relates to the technical field of display technologies, in particular to a display panel.

### BACKGROUND

A single-crystal silicon driving backplane is a driving substrate formed by using semiconductor components fabricated through a complementary metal oxide semiconductor (CMOS) process as driving units. Compared with a conventional active-matrix organic light-emitting diode (AMOLED) panel using a backplane of amorphous silicon, microcrystalline silicon, or low-temperature polysilicon thin-film transistors, the single-crystal silicon driving backplane has a higher carrier mobility. Therefore, a silicon-based organic light-emitting diode (OLED) display panel is a type of display panel with the most excellent performance in current products applied to the AR/VR field.

At present, the silicon-based OLED display panel integrates a traditional externally bonded display chip into a silicon-based driving backplane. The manufacturing method includes evaporating and fabricating an OLED light-emitting device on the silicon-based driving substrate. The specific process is to first deposit an anode, then fabricate a pixel definition layer, and then sequentially deposit an organic light-emitting layer and a cathode. This can fabricate pixel units of a smaller size, achieve display fineness exceeding the retinal level, and has many advantages such as high resolution, high integration, low power consumption, small volume, and light weight.

However, directly evaporating and fabricating the OLED light-emitting device on a silicon-based driving substrate may easily affect the silicon-based driving circuit, leading to damage to the driving circuit and making it unusable, thereby increasing costs.

### SUMMARY

The present disclosure provides a display panel, the display panel includes a glass substrate, a plurality of light-emitting units, a plurality of first bonding portions, and a silicon-based driving substrate. The glass substrate includes a first surface and a second surface opposite to each other, and the glass substrate defines a plurality of conductive vias extending from the first surface to the second surface. The plurality of conductive vias includes a plurality of first conductive vias. The plurality of light-emitting units are arranged on the first surface of the glass substrate; each light-emitting unit includes an anode electrode, an organic light-emitting layer, and a cathode electrode stacked in sequence in a direction away from the glass substrate. Each first bonding portion is arranged in a corresponding one of the first conductive vias; each first bonding portion is electrically connected to a corresponding anode electrode through a corresponding one of the first conductive vias. The silicon-based driving substrate is arranged on the second surface of the glass substrate; the silicon-based driving substrate includes a buffer layer close to a side of the glass substrate and a plurality of first bonding electrodes, and the plurality of first bonding electrodes are aligned and bonded in one-to-one correspondence with the plurality of first bonding portions, and at least part of the first bonding electrode is embedded in the buffer layer. The second surface of the glass substrate and a surface of a side of the buffer layer facing the glass substrate cooperates to form an accommodating groove, a reaction layer is arranged in the accommodating groove to absorb gas.

### BRIEF DESCRIPTION OF THE DRAWINGS

FIG. 1 is a schematic structural diagram of a display panel provided in a first embodiment of the present disclosure.

FIG. 2 is a schematic structural diagram of a foaming gel layer in the display panel shown in FIG. 1 after expansion.

FIG. 3a is a partial enlarged view of region A in the display panel shown in FIG. 1.

FIG. 3b is a partial enlarged view of region B in the display panel shown in FIG. 1.

FIG. 4 is a schematic structural diagram of a glass substrate in the display panel shown in FIG. 1.

FIG. 5 is a schematic structural diagram of a display panel provided in a second embodiment of the present disclosure.

### DETAILED DESCRIPTIONS

In the following description, specific details such as system architectures, interfaces, and techniques are provided for illustrative purposes only, not to limit the scope of the disclosure. The described embodiments should not be regarded as a limitation of the present disclosure, for those skilled in the art, other drawings may be acquired according to the drawings without any creative work.

In the following description, terms “first/second/third” are used only to distinguish similar objects and do not represent a specific order for the objects, and it is understood that the terms “first/second/third” may be interchanged in a specific order or sequence so that the embodiments of the present disclosure described can be implemented in an order other than the order or sequence described in the drawings and specification. The terms “first”, “second” and “third” in this disclosure are used for descriptive purposes only and are not to be construed as indicating or implying relative importance or as implicitly indicating the quantity of the technical features indicated. Thus, a feature defined as “first”, “second”, or “third” may explicitly or implicitly include at least one of the features. In the description of this disclosure, “multiple” means at least two, such as two, three, etc., unless otherwise expressly specified. All directional indications in the embodiments of this disclosure (e.g. up, down, left, right, front, back...) are only used to explain the relative position relationship and motion between the components in a specific attitude (as shown in the drawings). When the specific attitude changes, the directional indication may also change accordingly. Furthermore, the terms “including” and “having”, and any variation thereof, are intended to cover non-exclusive inclusion. For example, a process, method, system, product or device including a series of steps or units is not limited to the listed steps or units, but optionally also includes steps or units not listed, or optionally includes other steps or units inherent to those processes, methods, products or devices.

A term “embodiment” in the following description describes a subset of all possible embodiments, but it is understood that “embodiment” may be the same subset or a different subset of all possible embodiments, and may be combined with each other without conflict.

The technical solutions in the embodiments of the present disclosure will be described in detail below with reference to the accompanying drawings.

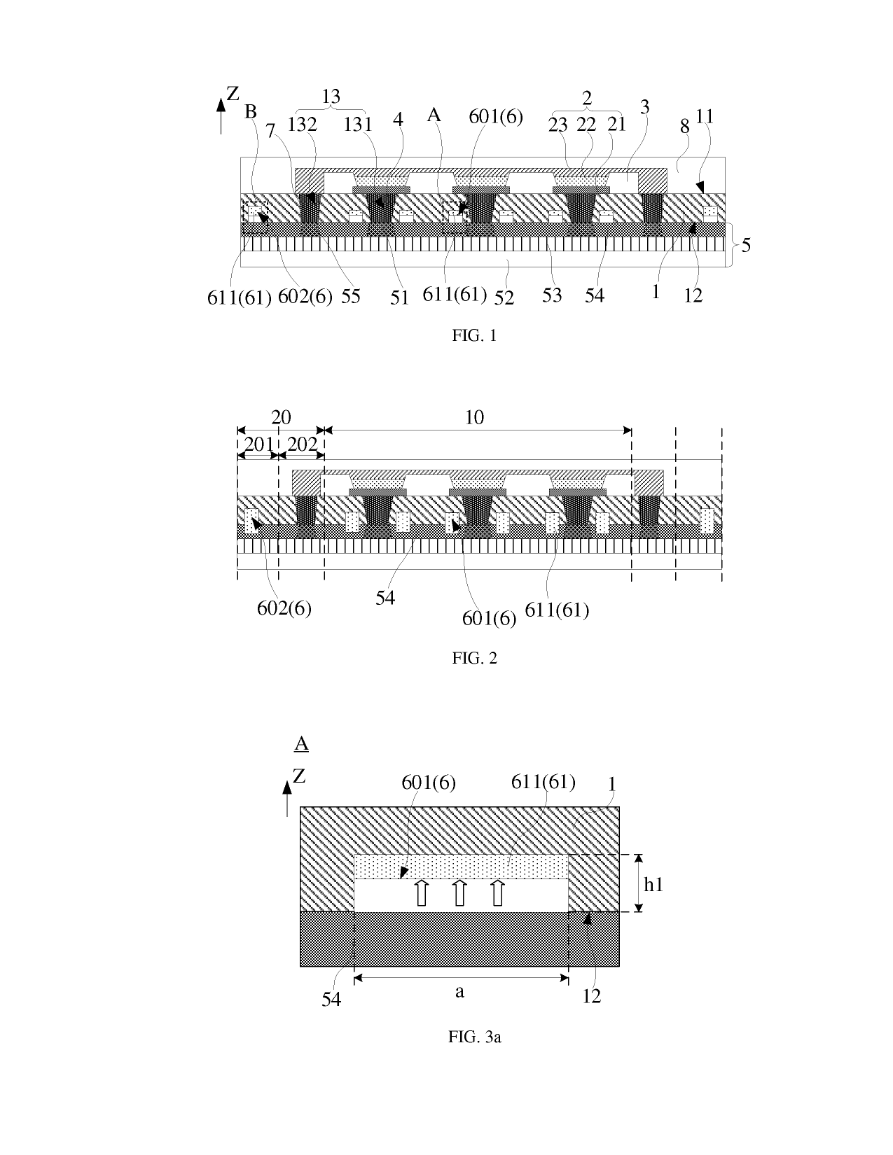

Referring to FIG. 1, FIG. 1 is a schematic structural diagram of a display panel provided in a first embodiment of the present disclosure. An embodiment of the present disclosure provides a display panel, which may be an OLED display panel; the display panel include a glass substrate 1, a plurality of light-emitting units 2, a plurality of first bonding portions 4, and a silicon-based driving substrate 5.

The glass substrate 1 includes a first surface 11 and a second surface 12 opposite to each other, and the glass substrate 1 defines a plurality of conductive vias 13 extending from the first surface 11 to the second surface 12. The plurality of conductive vias 13 includes a plurality of first conductive vias 131. The glass-via technology has the advantages of excellent high-frequency electrical characteristics, low cost, simple process, and strong mechanical stability compared with the silicon-via technology.

The plurality of light-emitting units 2 are arranged on the first surface 11 of the glass substrate 1; each light-emitting unit 2 includes an anode electrode 21, an organic light-emitting layer 22, and a cathode electrode 23 stacked in sequence in a direction away from the glass substrate 1. Specifically, the first surface 11 of the glass substrate 1 is further provided with a pixel definition layer 3, which protrudes from the glass substrate 1 and encloses a plurality of pixel accommodating regions (not shown); and the plurality of light-emitting units 2 are respectively arranged in the plurality of pixel accommodating regions. The plurality of pixel accommodating regions are arranged in one-to-one correspondence with the plurality of first conductive vias 131.

The anode electrode 21 may be arranged on a surface of the glass substrate 1 exposed through the pixel accommodating region, and the pixel definition layer 3 may cover an edge of each anode electrode 21 to avoid the situation where the anode electrodes 21 of adjacent light-emitting units 2 come into contact, resulting in signal crosstalk. Each organic light-emitting layer 22 may be arranged on a surface of a corresponding anode electrode 21 away from the glass substrate 1, and the cathode electrode 23 may be arranged on a side of the organic light-emitting layers 22 away from the anode electrode 21 and cover the organic light-emitting layers 22 of the plurality of light-emitting units 2 to form a full-surface common cathode. The anode electrodes 21 and the cathode electrode 23 respectively transmit anode driving signals and cathode driving signals to the organic light-emitting layers 22 to drive the organic light-emitting layers 22 to emit light.

In some embodiments, the light-emitting units 2 may include light-emitting units 2 with different emission colors, such as red light-emitting units, green light-emitting units, and blue light-emitting units, to achieve color display; the emission colors of the light-emitting units 2 are determined by the emission colors of the organic light-emitting layers 22. Alternatively, in other embodiments, the light-emitting units 2 may also be light-emitting units 2 of the same color, such as white, red, green, blue, or other colors, which may be specifically set according to actual needs; for example, the light-emitting units 2 may be white, and grayscale display may be achieved by controlling the brightness of the light-emitting units 2, and a color resist layer may further be additionally provided above each light-emitting unit 2 to achieve color display. For example, when the light-emitting units 2 are blue, red quantum dot layers may be additionally provided above some of the light-emitting units 2, and green quantum dot layers may be additionally provided above some of the light-emitting units 2 to achieve color display.

The plurality of first bonding portions 4 are arranged on the second surface 12 of the glass substrate 1, and each first bonding portion 4 may be at least partially arranged in a corresponding one of the first conductive vias 131; each first bonding portion 4 is electrically connected to a corresponding anode electrode 21 through a corresponding one of the first conductive vias 131 to transmit an anode driving signal to the anode electrode 21 of the corresponding light-emitting unit 2 through the corresponding one of the first conductive vias 131.

The silicon-based driving substrate 5 is arranged on one side of the second surface 12 of the glass substrate 1; the silicon-based driving substrate 5 further includes a plurality of first bonding electrodes 51, and the plurality of first bonding electrodes 51 are aligned and bonded in one-to-one correspondence with the plurality of first bonding portions 4 to control the light-emitting units 2 corresponding to the first bonding portions 4 to emit light. The silicon-based driving substrate 5 further includes a silicon substrate 52 and a driving circuit 53 arranged in a stacked manner; the silicon substrate 52 may refer to a substrate fabricated based on single-crystal silicon material; the driving circuit 53 may be electrically connected to the plurality of first bonding electrodes 51 and be configured to transmit an anode driving signal to the anode electrodes 21 through the first bonding portions 4. The driving circuit 53 may include an driving circuit 53 integrated on the silicon substrate 52 by using a CMOS (Complementary Metal-Oxide-Semiconductor) process. The driving circuit 53 may include a plurality of “3T1C” structures (three thin-film transistors and one capacitor) to achieve independent control and high-quality display of each light-emitting unit 2.

The silicon-based driving substrate 5 may further include a display control circuit (not shown) electrically connected to the driving circuit 53, and the display control circuit may control the light-emitting units 2 to display through the driving circuit 53; the display control circuit may be an integrated circuit (IC) integrated on the silicon-based driving substrate 5.

By arranging the light-emitting units 2 and the first bonding portions 4 on two opposite surfaces of the glass substrate 1, the plurality of first bonding portions 4 are respectively electrically connected with the anode electrodes 21 of the corresponding light-emitting units 2 through the first conductive vias 131, so as to realize the electrical coupling between the light-emitting units 2 and the silicon-based driving substrate 5, so that the silicon-based driving substrate 5 can drive the light-emitting units 2 to emit light. In this way, the light-emitting units 2 may not be directly fabricated on the silicon-based driving substrate 5, avoiding the problem that directly fabricating the light-emitting units 2 on the silicon-based driving substrate 5 damages the driving circuit 53 and causes a reduction in product yield.

The silicon-based driving substrate 5 further includes a buffer layer 54 close to a side of the glass substrate 1, and at least part of the first bonding electrode 51 is embedded in the buffer layer 54, and the buffer layer may be used to protect the driving circuit 53 from being damaged by the extrusion of the glass substrate 1.

The second surface 12 of the glass substrate 1 and a surface of a side of the buffer layer 54 facing the glass substrate 1 cooperates to form at least one accommodating groove 6; the accommodating groove 6 may be only arranged on the second surface 12 of the glass substrate 1, only arranged on the surface of the side of the buffer layer 54 facing the glass substrate 1, or respectively arranged on the glass substrate 1 and the buffer layer 54. A reaction layer 61 is arranged in the accommodating groove 6, and the reaction layer 61 absorbs gas; the manner in which the reaction layer 61 absorbs gas may be physical adsorption, chemical adsorption, physical absorption, chemical absorption, or the like.

Those skilled in the art can understand that the manner of drilling holes in the glass substrate 1 to electrically connect the anodes and the silicon-based driving substrate 5 increases a path for the gas to enter inside of the display panel through the conductive vias 13 in the glass substrate 1; and since the glass substrate 1 and the silicon-based driving substrate 5 are integrally encapsulated, the encapsulation difficulty is relatively high, and progressive failure is likely to occur, resulting in gas entry; additionally, organic film layers and other materials in the display panel may release gas; the gas entering the inside of the display panel and/or the gas generated inside the display panel may affect the reliability and durability of the display panel, thereby adversely affecting the service life of the display panel.

By arranging the reaction layer 61 capable of absorbing gas in the accommodating groove 6 between the glass substrate 1 and the silicon-based driving substrate 5, the gas entering the inside of the display panel and/or the gas generated inside the display panel is absorbed, so that the damage of the gas to each film layer of the display panel is reduced, the reliability and durability of the display panel is improved, and the service life is effectively increased. In addition, by arranging the buffer layer 54 on the silicon-based driving substrate 5, friction between the silicon-based driving substrate 5 and the glass substrate 1 is increased, and the risk of misalignment between the glass substrate 1 and the silicon-based driving substrate 5 is avoided; furthermore, the buffer layer 54 may play a buffering role, avoiding the situation where the glass substrate 1 directly extrudes the silicon-based driving substrate 5 to cause damage to the film layer, and further increasing the service life of the display panel.

In an embodiment, the reaction layer 61 may include a foaming gel layer 611, and the foaming gel layer 611 may be used to absorb the gas entering the inside of the display panel and/or the gas generated inside the display panel, so as to reduce the damage of the gas to each film layer of the display panel. When the foaming gel layer 611 absorbs the gas in the display panel, the foaming gel layer 611 may undergo foaming nucleation growth to expand the volume of the foaming gel layer 611; therefore, in the embodiment of the present disclosure, the foaming gel layer 611 may only fill part of the space of the accommodating groove 6, so that the accommodating groove 6 has enough space to accommodate the volume-expanded foaming gel layer 611.

With reference to FIG. 1 and FIG. 2, FIG. 2 is a schematic structural diagram of a foaming gel layer in the display panel shown in FIG. 1 after expansion; the buffer layer 54 may further be of a porous structure and have elasticity, and when the volume-expanded foaming gel layer 611 contacts the buffer layer 54, the buffer layer 54 may be deformed by being compressed by the foaming gel layer 611, so as to avoid the situation where the volume-expanded foaming gel layer 611 compresses other film layers of the display panel to cause film layer stress.

Gas may be generated in the display panel during the manufacturing process and during use, and the foaming gel layer 611 may continuously absorb the gas in the display panel and expand; the pores in the buffer layer 54 may provide space for the expansion of the foaming gel layer 611, and the elastic buffer layer 54 may also be deformed under the compression of the foaming gel layer 611 to better provide space for the foaming gel layer 611. That is, the volume expansion of the foaming gel layer 611 after absorbing gas may be offset by the volume reducing of the buffer layer 54 under compression, reducing the risk of the foaming gel layer 611 compressing other film layers of the display panel and damaging the display panel during the manufacturing process and use.

In an embodiment, the foaming gel layer 611 may include polyurethane soft foam gel materials and a catalytic phase material. The polyurethane soft foam gel materials can be foamed into a polyurethane foam material at room temperature in a system with a catalytic phase material. Specifically, the catalytic phase material may be an amine or oxide catalyst.

In an embodiment, the surface roughness of the buffer layer 54 may be greater than or equal to 3 microns and less than or equal to 6.5 microns to increase the friction between the silicon-based driving substrate 5 and the glass substrate 1 and reduce the risk of misalignment between the glass substrate 1 and the silicon-based driving substrate 5. The surface roughness of the buffer layer 54 may be any value among 3 microns, 4 microns, 5 microns, 6 microns, or 6.5 microns.

The buffer layer 54 may include a fiber mat; the fiber mat may be prepared by an electrospinning process; specifically, a high-voltage electrostatic field may be applied to make a polymer solution or melt spray into fine droplets, which are then stretched into fibers under the action of an electric field force. This process can produce continuous fibers with a diameter between tens of nanometers and hundreds of nanometers, which have a high surface area, high porosity, and excellent mechanical properties. The highly elastic fiber mat is beneficial to providing space for the expansion of the foaming gel layer 611. The material of the fiber mat may be any one of polyester, polyamide, polyvinyl alcohol, polyacrylonitrile, polyurethane, or poly(p-phenylene terephthalamide).

In other embodiments, the buffer layer 54 may further include a porous film layer, such as a polyimide porous film.

Referring to FIG. 2, in an embodiment, the display panel may have a display region 10 and a non-display region 20 surrounding the display region 10; the region of the display panel corresponding to the display region 10 may include a plurality of light-emitting units 2 for displaying images; the region of the display panel corresponding to the non-display region 20 may provide structures such as circuits, pads, and a border, and the border may be used to cover structures such as the circuits and the pads.

The non-display region 20 may include a frame region 201 and a transition region 202 located between the display region 10 and the frame region 201. The transition region 202 may be arranged close to the display region 10, and the width of the transition region 202 is generally two-thirds of the width of the non-display region 20. The region of the display panel corresponding to the transition region 202 may be used to set signal lines such as control circuits; the frame region 201 may be arranged away from the display region 10, and the width of the frame region 201 is generally one-third of the width of the non-display region 20. The region of the display panel corresponding to the frame region 201 may be used to set borders and insulating film layers.

As shown in FIG. 2, in an embodiment, the accommodating groove 6 may include a first groove 601 arranged in the display region 10 and a second groove 602 arranged in the frame region 201. The reaction layer 61 arranged in the first groove 601 may be used to absorb gas near the first conductive vias 131, so as to reduce the risk of gas inside the display panel entering the light-emitting units 2 through the first conductive vias 131 and damaging the organic light-emitting layers 22. The reaction layer 61 arranged in the second groove 602 may be used to absorb gas at an encapsulation edge of the display panel, so as to reduce the risk of external gas entering the internal film layers of the display panel.

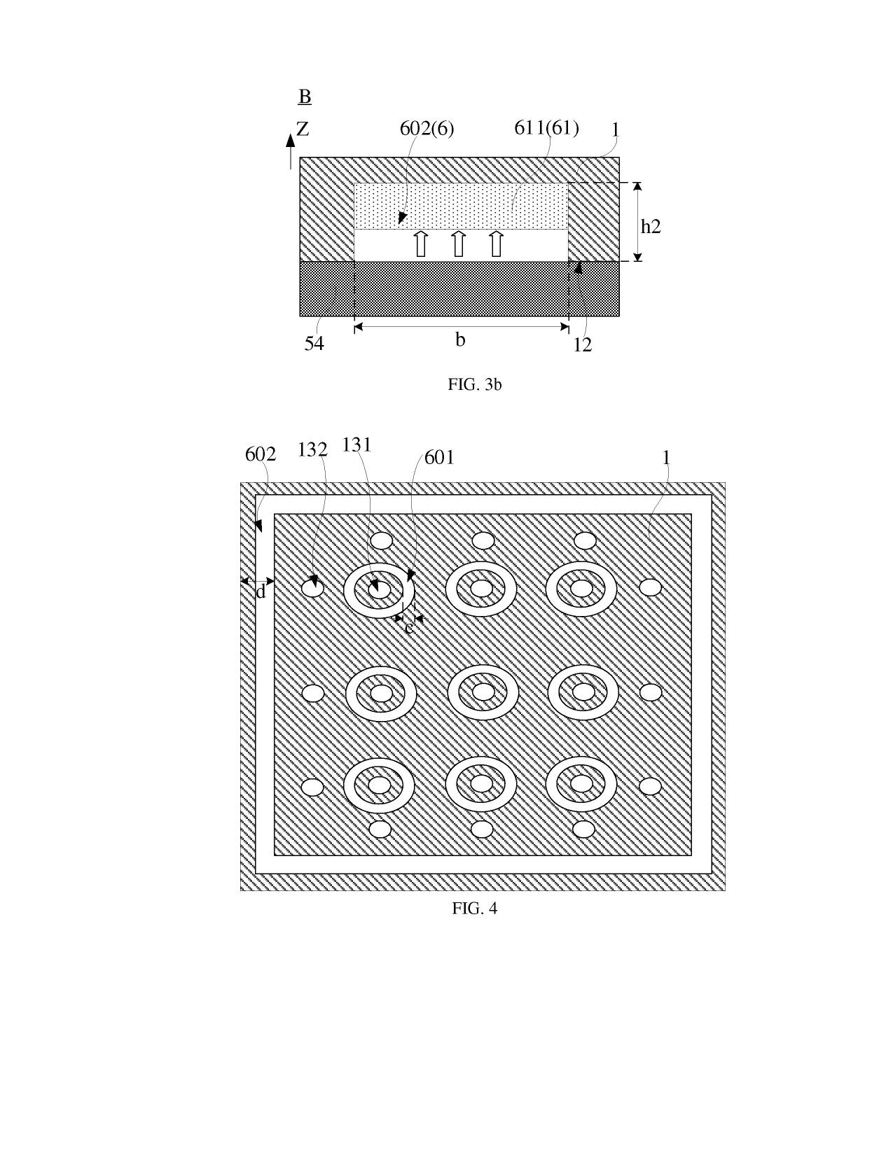

Referring to FIGS. 3a and 3b, FIG. 3a is a partial enlarged view of region A in the display panel shown in FIG. 1; FIG. 3b is a partial enlarged view of region B in the display panel shown in FIG. 1. A depth h1 of the first groove 601 may be less than a depth h2 of the second groove 602. It can be understood that the frame region 201 may be located at an edge of the display panel, and progressive encapsulation failure, an encapsulation fault generated during the encapsulation process of the display panel, is likely to occur at this position; by increasing the depth h2 of the second groove 602 located in the frame region 201, the volume of the reaction layer 61 that can be filled in the second groove 602 is larger, so as to enhance the gas absorption capacity of the reaction layer 61 in the second groove 602. In addition, since no control circuits or other signal lines are arranged in the frame region 201, the increased depth of the second groove 602 may not affect the signal transmission of the display panel.

The depth h1 of the first groove 601 may be a dimension of the first groove 601 along a thickness direction Z of the display panel, and the depth h2 of the second groove 602 may be a dimension of the second groove 602 along the thickness direction Z of the display panel.

As shown in FIG. 3a and FIG. 3b, the first groove 601 may be arranged on the second surface 12 of the glass substrate 1; and the first groove 601 extends from the second surface 12 of the glass substrate 1 toward the light-emitting units 2 along the thickness direction Z. The depth h1 of the first groove 601 may be greater than or equal to one-third of the thickness of the glass substrate 1 to accommodate a sufficient amount of the foaming gel layer 611; and the depth h1 of the first groove 601 may be less than or equal to one-half of the thickness of the glass substrate 1 to avoid the situation where the structural strength of the glass substrate 1 is reduced due to the excessively large depth of the first groove 601.

A width a of the first groove 601 may be greater than or equal to 0.5 microns and less than or equal to 1 micron to ensure that the first groove 601 has enough space to accommodate the foaming gel layer 611 without affecting a dense arrangement of the first conductive vias 131. The width a of the first groove 601 may be any value among 0.5 microns, 0.6 microns, 0.7 microns, 0.8 microns, 0.9 microns, and 1 micron.

The second groove 602 may also be arranged on the second surface 12 of the glass substrate 1, and the second groove 602 may extend from the second surface 12 of the glass substrate 1 toward the light-emitting units 2 along the thickness direction Z. The depth h2 of the second groove 602 may be greater than or equal to one-half of the thickness of the glass substrate 1 to ensure that the depth h2 of the second groove 602 is greater than the depth h1 of the first groove 601, so as to accommodate a larger volume of the foaming gel layer 611 in the second groove 602. And the depth h2 of the second groove 602 may be less than or equal to three-fifths of the thickness of the glass substrate 1 to avoid the situation where the structural strength of the glass substrate 1 is reduced due to the excessively large depth of the second groove 602.

A width b of the second groove 602 may be greater than or equal to 1 micron and less than or equal to 50 microns to ensure that the second groove 602 has enough space to accommodate a larger volume of the foaming gel layer 611 without affecting the signal lines arranged in the transition region 202.The width b of the second groove 602 may be any value among 1 micron, 10 microns, 30 microns, 40 microns, and 50 microns.

Referring to FIG. 4, FIG. 4 is a schematic structural diagram of a glass substrate in the display panel shown in FIG. 1; in an embodiment, a shape of a projection of the first groove 601 on the glass substrate 1 along the thickness direction Z may be annular, that is, the at least one first groove 601 may be arranged around the first conductive via(s) 131, so as to further improve the ability of the foaming gel layer 611 in the first groove 601 to absorb gas near the first conductive via(s) 131.

The first groove 601 and a corresponding one of the first conductive vias 131 may be coaxially arranged, and the first groove 601 may be arranged at an interval from the corresponding one of the first conductive vias 131; a distance c between the first groove 601 and the corresponding first conductive via 131 may be greater than or equal to 1 micron and less than or equal to 2 microns to avoid the situation where the structural strength of the first conductive vias 131 is affected due to an excessively small distance, and additionally, avoid the situation where the foaming gel layer 611 in the first groove 601 fails to effectively absorb the gas near the corresponding first conductive via 131 due to an excessively large distance. The distance c between the first groove 601 and the corresponding first conductive via 131 may be any value among 1 micron, 1.2 microns, 1.6 microns, 1.8 microns, or 2 microns.

With reference to FIG. 2 and FIG. 4, the second groove 602 may be an annular groove surrounding the display region 10, and a side of the second groove 602 close to the display region 10 may be at a distance d of greater than or equal to 50 microns and less than or equal to 100 microns from an edge of the display panel; this is convenient for the foaming gel layer 611 in the second groove 602 to absorb gas entering the inside of the display panel from the edge of the display panel. The distance d between the side of the second groove 602 close to the display region 10 and the edge of the display panel may be any value among 50 microns, 60 microns, 70 microns, 80 microns, 90 microns, or 100 microns.

In other embodiments, a plurality of second grooves 602 may be provided, and the plurality of second grooves 602 may be arranged around the display region 10 at intervals.

As shown in FIG. 3a, an initial volume of the foaming gel layer 611 in the first groove 601 may be greater than or equal to 30% of the volume of the first groove 601 and less than or equal to 40% of the volume of the first groove 601. It can be understood that when the volume of the foaming gel layer 611 arranged in the first groove 601 is excessively small, the gas absorption capacity may be reduced; when the volume of the foaming gel layer 611 is excessively large, a remaining space in the first groove 601 and the pores of the buffer layer 54 may not be sufficient to accommodate the volume-expanded foaming gel layer 611. Therefore, setting the initial volume of the foaming gel layer 611 to be greater than or equal to 30% and less than or equal to 40% of the volume of the first groove 601 may ensure the gas absorption capacity of the foaming gel layer 611 and reduce the risk of the expanded foaming gel layer 611 extruding other film layers of the display panel.

The initial volume of the foaming gel layer 611 in the first groove 601 may be any value among 30%, 32%, 35%, 38%, or 40% of the volume of the first groove 601. The initial volume of the foaming gel layer 611 refers to the volume of the foaming gel layer 611 before it starts to expand after absorbing gas.

As shown in FIG. 3b, similarly, an initial volume of the foaming gel layer 611 in the second groove 602 may be greater than or equal to 50% of the volume of the second groove 602 and less than or equal to 60% of the volume of the second groove 602, so as to ensure the gas absorption capacity of the foaming gel layer 611 in the second groove 602 and reduce the risk of the expanded foaming gel layer 611 squeezing other film layers of the display panel. In addition, by increasing the volume ratio of the foaming gel layer 611 in the second groove 602 to the second groove 602, the gas absorption capacity of the foaming gel layer 611 in the second groove 602 may be further enhanced, thereby reducing the risk of gas entering the display panel due to progressive encapsulation failure.

The initial volume of the foaming gel layer 611 in the second groove 602 may be any value among 50%, 52%, 55%, 58%, or 60% of the volume of the second groove 602.

Referring to FIG. 1, in an embodiment, the conductive vias 13 may further include a plurality of second conductive vias 132 arranged on a peripheral side of the plurality of first conductive vias 131; the display panel may further include a plurality of second bonding portions 7 at least partially arranged in the second conductive vias 132, and each second bonding portion 7 may be electrically connected to the cathode electrode 23 through a corresponding one of the second conductive vias 132 to transmit the cathode driving signals to the cathode electrode 23 of the light-emitting units 2 through the corresponding second conductive via 132. The silicon-based driving substrate 5 may further include a plurality of second bonding electrodes 55, each second bonding electrode 55 may be aligned and bonded in one-to-one correspondence with the plurality of second bonding portions 7, and the silicon-based driving substrate 5 may transmit the cathode driving signals to the cathode electrode 23 through the second bonding electrodes 55 and the second bonding portions 7 to control the light-emitting unit 2 to emit light.

As shown in FIG. 1, in a specific embodiment, the glass substrate 1 may be further provided with an encapsulation layer 8 for protecting the light-emitting units 2 on the glass substrate 1, isolating external water and oxygen, and avoiding the failure of the light-emitting units 2 caused by the invasion of water and oxygen; specifically, the encapsulation layer 8 may cover a surface of a side of the cathode electrode 23 away from the anode electrodes 21 and overlaps on a surface of the glass substrate 1 not covered by the light-emitting units 2.

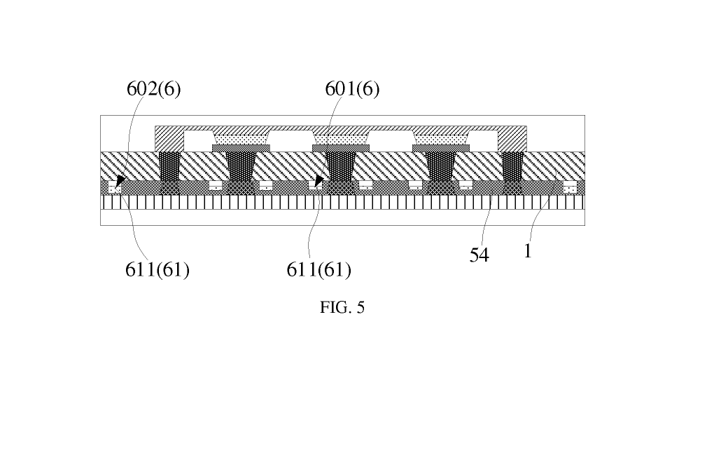

Referring to FIG. 5, FIG. 5 is a schematic structural diagram of a display panel provided in a second embodiment of the present disclosure; the structure of the display panel provided in the second embodiment of the present disclosure is basically the same as that of the display panel provided in the first embodiment of the present disclosure, and the difference is that in the second embodiment of the present disclosure, the first groove 601 and the second groove 602 may both be arranged on a surface of the buffer layer 54 facing the glass substrate 1. Arranging the foaming gel layer 611 in the accommodating groove 6 on the buffer layer 54 allows the foaming gel layer 611 to perform foaming nucleation growth toward the pores of the surrounding buffer layer 54, improves a pore utilization rate of the buffer layer 54, and further reduces the risk of the expanded foaming gel layer 611 squeezing other film layers of the display panel.

In other embodiments, the first groove 601 may also be arranged on the second surface 12 of the glass substrate 1, and the second groove 602 may also be arranged on a surface of the buffer layer 54 facing the glass substrate 1; or the first groove 601 may also be arranged on a surface of the buffer layer 54 facing the glass substrate 1, and the second groove 602 may also be arranged on the second surface 12 of the glass substrate 1.

The embodiment of the present disclosure provides a display panel including a glass substrate 1, a plurality of light-emitting units 2, a plurality of first bonding portions 4, and a silicon-based driving substrate 5. The glass substrate 1 includes a first surface 11 and a second surface 12 opposite to each other, and the glass substrate 1 has a plurality of conductive vias 13 extending from the first surface 11 to the second surface 12. The plurality of conductive vias 13 includes a plurality of first conductive vias 131. The plurality of light-emitting units 2 are arranged on the first surface 11 of the glass substrate 1; each light-emitting unit 2 includes an anode electrode 21, an organic light-emitting layer 22, and a cathode electrode 23 stacked in sequence in a direction away from the glass substrate 1. Each first bonding portion 4 is arranged in a corresponding one of the first conductive vias 131; each first bonding portion 4 is electrically connected to a corresponding anode electrode 21 through a corresponding one of the first conductive vias 131. The silicon-based driving substrate 5 is arranged on one side of the second surface 12 of the glass substrate 1; the silicon-based driving substrate 5 further includes a plurality of first bonding electrodes 51 and a buffer layer 54 arranged on a side close to the glass substrate 1, and the plurality of first bonding electrodes 51 are aligned and bonded in one-to-one correspondence with the plurality of first bonding portions 4

By separating the light-emitting units and the driving circuit onto different substrates and using conductive vias for electrical connection, the invention avoids direct manufacturing of light-emitting units on the silicon-based driving substrate, protecting the driving circuit and improving yield. The gas-absorbing reaction layer in the accommodating groove reduces gas damage to film layers, enhancing reliability and service life. The buffer layer increases friction and provides buffering, preventing misalignment and film damage, further contributing to a longer lifespan for the display panel. At least part of the first bonding electrode 51 may be embedded in the buffer layer 54. The second surface 12 of the glass substrate 1 and a side of the buffer layer 54 facing the glass substrate 1 cooperates to form at least one accommodating groove 6; a reaction layer 61 is arranged in the accommodating groove 6, and the reaction layer 61 absorbs gas. By arranging the light-emitting units 2 and the first bonding parts 4 on two opposite surfaces of the glass substrate 1 respectively, after each of the first bonding portions 4 is in contact and electrically connected to the anode electrode 21 of the corresponding one of the light-emitting units 2 through the corresponding first conductive via 131 respectively, the electrical coupling between the light-emitting units 2 and the silicon-based driving substrate 5 is achieved, enabling the silicon-based driving substrate 5 to drive the light-emitting units 2 to emit light. In this way, the light-emitting units 2 may not be directly fabricated on the silicon-based driving substrate 5, avoiding the problem that directly fabricating the light-emitting units 2 on the silicon-based driving substrate 5 may damage the pixel driving circuit and lead to a reduction in product yield. Furthermore, by arranging the reaction layer 61 capable of absorbing gas in the accommodating groove 6 between the glass substrate 1 and the silicon-based driving substrate 5, the gas entering the inside of the display panel and/or the gas generated inside the display panel is absorbed, thereby reducing the damage of the gas to each film layer of the display panel, improving the reliability and durability of the display panel, and effectively increasing the service life of the display panel. In addition, by arranging the buffer layer 54 on the silicon-based driving substrate 5, the friction between the silicon-based driving substrate 5 and the glass substrate 1 is increased to avoid misalignment between the glass substrate 1 and the silicon-based driving substrate 5; additionally, the buffer layer 54 can also play a buffering role, avoiding the situation where the glass substrate 1 directly squeezes the silicon-based driving substrate 5 and causes damage to the film layers, and therefore further increasing the service life of the display panel.

The above descriptions are only embodiments of the present disclosure and do not limit the patent scope of the present disclosure. Any equivalent structural or equivalent process transformations made using the descriptions and drawings of the present disclosure, or direct or indirect disclosures in other related technical fields, are all included in the patent protection scope of the present disclosure.

What is claimed is:

1. A display panel, comprising:
a glass substrate, comprising a first surface and a second surface opposite to each other, wherein the glass substrate defines a plurality of conductive vias extending from the first surface to the second surface, and the plurality of conductive vias comprises a plurality of first conductive vias;
a plurality of light-emitting units arranged on the first surface of the glass substrate, wherein each light-emitting unit comprises an anode electrode, an organic light-emitting layer, and a cathode electrode stacked in sequence in a direction away from the glass substrate;
a plurality of first bonding portions, wherein each first bonding portion is arranged in a corresponding one of the first conductive vias, and each first bonding portion is electrically connected to a corresponding anode electrode through a corresponding one of the first conductive vias; and
a silicon-based driving substrate arranged on the second surface of the glass substrate, wherein the silicon-based driving substrate comprises a buffer layer close to a side of the glass substrate and a plurality of first bonding electrodes, the plurality of first bonding electrodes are aligned and bonded in one-to-one correspondence with the plurality of first bonding portions, and at least part of the first bonding electrode is embedded in the buffer layer;
wherein the second surface of the glass substrate and a surface of a side of the buffer layer facing the glass substrate cooperates to form an accommodating groove, and a reaction layer is arranged in the accommodating groove to absorb gas.

2. The display panel according to claim 1, wherein the reaction layer comprises a foaming gel layer, the foaming gel layer fills only part of the space of the accommodating groove, and the foaming gel layer undergoes a foaming nucleation growth to expand a volume of the foaming gel layer when the foaming gel layer absorbs the gas.

3. The display panel according to claim 2, wherein the buffer layer is of a porous structure and has elasticity, and the buffer layer is deformed by being compressed by the foaming gel layer when a volume-expanded foaming gel layer contacts the buffer layer.

4. The display panel according to claims claim 1, wherein the display panel has a display region and a non-display region surrounding the display region, the non-display region comprises a frame region and a transition region located between the display region and the frame region; and
the accommodating groove comprises a first groove arranged in the display region and a second groove arranged in the frame region, a depth of the first groove is less than a depth of the second groove, the depth of the first groove is a dimension of the first groove along a thickness direction of the display panel, and the depth of the second groove is a dimension of the second groove along the thickness direction of the display panel.

5. The display panel according to claim 4, wherein the second groove is an annular groove surrounding the display region, and a side of the second groove close to the display region is at a distance of greater than or equal to 50 microns and less than or equal to 100 microns from an edge of the display panel.

6. The display panel according to claim 4, wherein the transition region is arranged close to the display region, and the frame region is arranged away from the display region.

7. The display panel according to claim 4, wherein the first groove and the second groove are arranged on the second surface of the glass substrate; or
the first groove and the second groove are arranged on a surface of the buffer layer facing the glass substrate; or
the first groove is arranged on the second surface of the glass substrate while the second groove is arranged on the surface of the buffer layer facing the glass substrate; or
the first groove is arranged on the surface of the buffer layer facing the glass substrate while the second groove is arranged on the second surface of the glass substrate.

8. The display panel according to claim 7, wherein the first groove and the second groove are arranged on the second surface of the glass substrate;
the depth of the first groove is greater than or equal to one-third of a thickness of the glass substrate and is less than or equal to one-half of the thickness of the glass substrate, the depth of the second groove is greater than or equal to one-half of the thickness of the glass substrate and is less than or equal to three-fifths of the thickness of the glass substrate; and
the width of the first groove is greater than or equal to 0.5 microns and is less than or equal to 1 micron, and the width of the second groove is greater than or equal to 1 micron and is less than or equal to 50 microns.

9. The display panel according to claim 8, wherein a shape of a projection of the first groove on the glass substrate along the thickness direction is annular, the first groove and a corresponding one of the first conductive vias are coaxially arranged, the first groove is arranged at an interval from the corresponding one of the first conductive vias, and a distance between the first groove and the corresponding first conductive via is greater than or equal to 1 micron and be less than or equal to 2 microns; or a side of the second groove close to the display region is at a distance of greater than or equal to 50 microns and less than or equal to 100 microns from an edge of the display panel.

10. The display panel according to claim 8, wherein an initial volume of the foaming gel layer in the first groove is greater than or equal to 30% of the volume of the first groove and is less than or equal to 40% of the volume of the first groove, and an initial volume of the foaming gel layer in the second groove is greater than or equal to 50% of the volume of the second groove and is less than or equal to 60% of the volume of the second groove.

11. The display panel according to claim 2, wherein the foaming gel layer comprise polyurethane soft foam gel materials and a catalytic phase material.

12. The display panel according to claim 1, wherein the surface roughness of the buffer layer is greater than or equal to 3 microns and is less than or equal to 6.5 microns;
the buffer layer comprises a fiber mat or a polyimide porous film, the material of the fiber mat is any one of polyester, polyamide, polyvinyl alcohol, polyacrylonitrile, polyurethane, or poly(p-phenylene terephthalamide).

13. The display panel according to claim 1, wherein the buffer layer further comprises a porous film layer.

14. The display panel according to claim 1, wherein the first surface of the glass substrate is further provided with a pixel definition layer, the pixel definition layer protrudes from the glass substrate and encloses a plurality of pixel accommodating regions, and the plurality of light-emitting units are respectively arranged in the plurality of pixel accommodating regions.

15. The display panel according to claim 14, wherein the plurality of pixel accommodating regions are arranged in one-to-one correspondence with the plurality of first conductive vias.

16. The display panel according to claim 14, wherein the anode electrode of each light-emitting unit is arranged on a surface of the glass substrate exposed through the pixel accommodating regions, and the pixel definition layer covers an edge of each anode electrode.

17. The display panel according to claim 1, wherein the conductive vias further comprises a plurality of second conductive vias arranged on a peripheral side of the plurality of first conductive vias, the display panel further comprises a plurality of second bonding portions that are at least partially arranged in the second conductive vias, and each second bonding portion is electrically connected to the cathode electrode through a corresponding one of the second conductive vias.
